(19) United States
(12) Patent Application Publication
(10) Pub. No.: US 2025/0275078 A1
(43) Pub. Date: Aug. 28, 2025

(54) PLATE, ELECTRONIC DEVICE CASING AND RACK ASSEMBLY

(71) Applicant: Wiwynn Corporation, New Taipei City (TW)

(72) Inventors: CHIEN-YUN HSU, New Taipei City (TW); YUNG-TI CHUNG, New Taipei City (TW); JHENG-YING JIANG, New Taipei City (TW)

(21) Appl. No.: 18/889,594

(22) Filed: Sep. 19, 2024

(30) Foreign Application Priority Data
Feb. 23, 2024 (TW) 113106488

(51) Int. Cl. H05K 7/14

(52) U.S. Cl. CPC H05K 7/1487

(57) ABSTRACT

A plate includes a support portion and at least one embossing structure. The support portion has a support surface. The embossing structure is formed on the support surface. Times of an average moment of inertia of cross sections of the plate in a first direction fall within a range from 1.14 to 1.18.

### CROSS-REFERENCE TO RELATED APPLICATIONS

This non-provisional application claims priority under 35 U.S.C. § 119 (a) on Patent Application No(s). 113106488 filed in Taiwan, R.O.C. on Feb. 23, 2024, the entire contents of which are hereby incorporated by reference.

### TECHNICAL FIELD

The disclosure relates a plate, an electronic device casing and a rack assembly.

### BACKGROUND

In general, a bottom plate of a casing of a server is mainly used to support various electronic components in the server. Therefore, in order to enable the bottom plate to have a sufficient structural strength for supporting those electronic component while not being deformed, the bottom plate of the casing of the server is required to have a sufficient thickness, but this may against lightweight requirement and carbon reduction requirement. As a result, how to achieve the lightweight requirement and the carbon reduction requirement while satisfying the structural strength of the bottom plate of the casing is one of the crucial topics in this field.

### SUMMARY

One embodiment of the disclosure provides a plate. The plate includes a support portion and at least one embossing structure. The support portion has a support surface. The embossing structure is formed on the support surface. Times of an average moment of inertia of cross sections of the plate in a first direction fall within a range from 1.14 to 1.18.

Another embodiment of the disclosure provides an electronic device casing. The electronic device casing includes a first plate and two second plates. The first plate includes a support portion and at least one embossing structure. The support portion has a support surface. The embossing structure is formed on the support surface, and times of an average moment of inertia of cross sections of the first plate in a first direction fall within a range from 1.14 to 1.18. The two second plates stand on two opposite sides of the support surface of the support portion of the first plate, and the first plate and the two second plates together form an accommodation space.

Still another embodiment of the disclosure provides a rack assembly. The rack assembly includes a rack and an electronic device casing. The electronic device casing is mounted in the rack and includes a first plate and two second plates. The first plate includes a support portion and at least one embossing structure. The support portion has a support surface, the at least one embossing structure is formed on the support surface, and times of an average moment of inertia of cross sections of the first plate in a first direction fall within a range from 1.14 to 1.18. The two second plates stand on two opposite sides of the support surface of the support portion of the first plate, and the first plate and the two second plates together form an accommodation space.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a rack assembly according to a first embodiment of the disclosure;

FIG. 2 is a perspective view of an electronic device casing in FIG. 1;

FIG. 3 is a top view of the electronic device casing in FIG. 2;

FIG. 4 is a curve chart showing a relationship between times of average moment of inertia and improvement rate of downward bending deformation;

FIG. 5 is a partially enlarged view of a unit of a first plate along a first direction in FIG. 3;

FIG. 6 is a partially enlarged view of a unit of the first plate along a second direction in FIG. 3;

FIG. 7 shows a cross section in u-v coordinate system;

FIG. 8 shows the cross section in x-y coordinate system;

FIG. 9 is a top view of an electronic device casing according to a second embodiment of the disclosure;

FIG. 10 is a partially enlarged view of a unit of a first plate along a first direction in FIG. 9; and

FIG. 11 is a partially enlarged view of a unit of the first plate along a second direction in FIG. 9.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

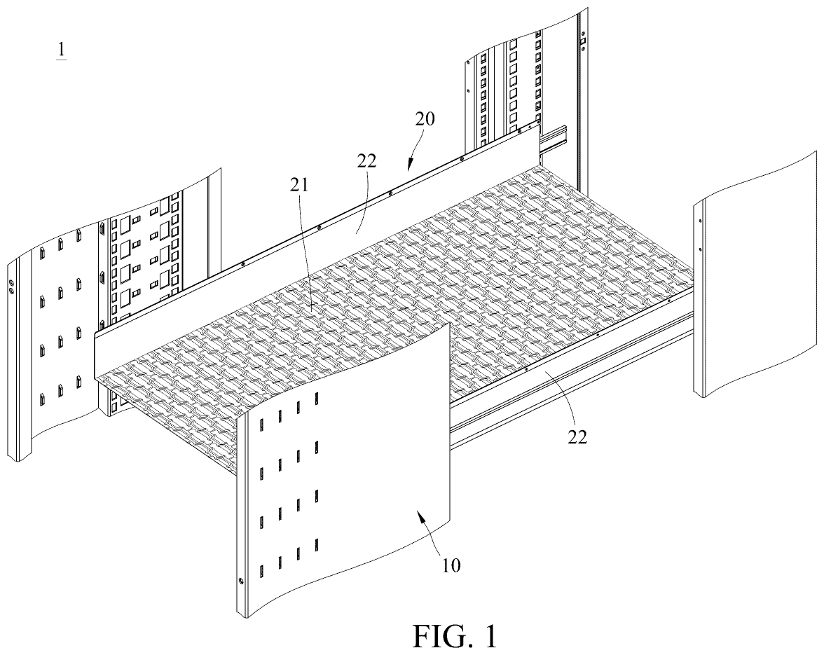

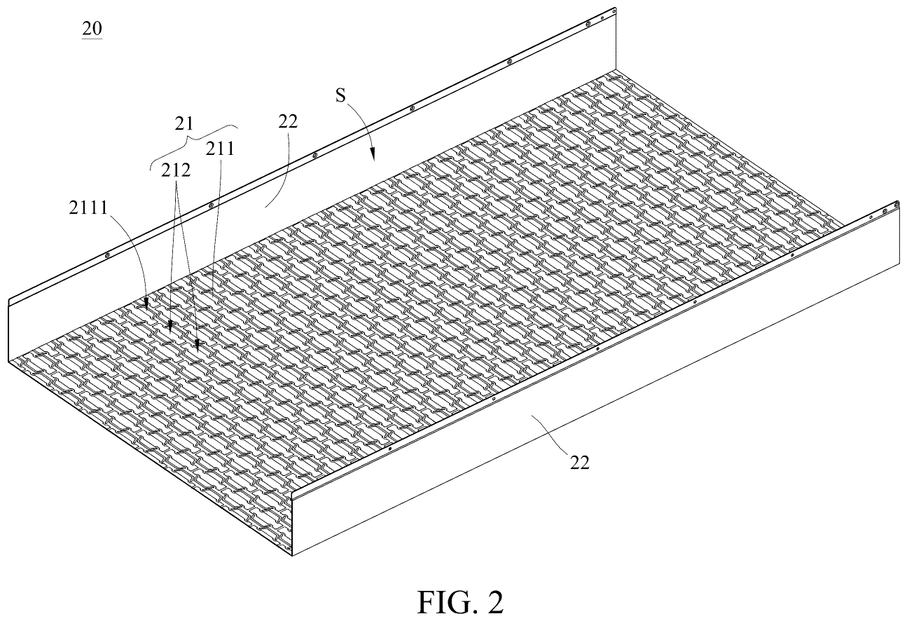

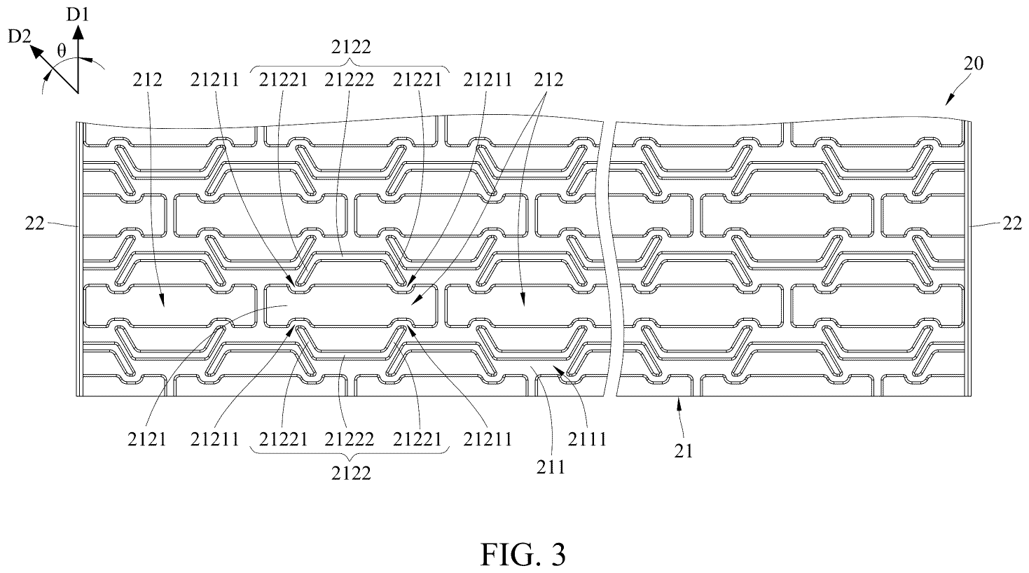

Referring to FIGS. 1 to 3, FIG. 1 is a perspective view of a rack assembly according to a first embodiment of the disclosure, FIG. 2 is a perspective view of an electronic device casing in FIG. 1, and FIG. 3 is a top view of the electronic device casing in FIG. 2.

In this embodiment, the rack assembly 1 includes a rack 10 and an electronic device casing 20. The rack 10 is, for example, a server rack. The electronic device casing 20 is, for example, a server casing, and the electronic device casing 20 is mounted in the rack 10.

The electronic device casing 20 includes a first plate 21 and two second plates 22. The first plate 21 includes a support portion 211 and a plurality of embossing structures 212. The support portion 211 has a support surface 2111. The second plates 22 respectively stand on two opposite sides of the support surface 2111 of the support portion 211 of the first plate 21. The first plate 21 and the second plates 22 together form an accommodation space S, and the accommodation space S is, for example, configured to accommodate electronic components of a server (not shown), such as a motherboard, hard disk drives and fans. The embossing structures 212 are formed on the support surface 2111 and are arranged in an array. The embossing structures 212 may be formed on the support surface 2111 by performing an embossing process along a direction from one surface of the support portion 211 facing away from the support surface 2111 towards the support surface 2111. For example, each of the embossing structures 212 includes a main portion 2121 and two branch portions 2122. The main portion 2121, for example, has four recesses 21211, two of the recesses 21211 are located at one side of the main portion 2121 and are spaced apart from each other, and the other two of the recesses 21211 are located at another side of the main portion 2121 and are spaced apart from each other. As shown in FIG. 3, the recesses 21211 are symmetrically recessed inwards from two opposite long sides of the main portion 2121 which substantially has a rectangular shape. Each of the two branch portions 2122 includes two end parts 21221 and a connection part 21222 connected to the two end parts 21221. The two end parts 21221 of one of the branch portions 2122 respectively correspond to two of the recesses 21211 located at one side of the main portion 2121, and the two end parts 21221 of the other one of the branch portions 2122 respectively correspond to the other two of the recesses 21211 located at another side of the main portion 2121. As shown in FIG. 3, the connection parts 21222 are spaced apart from the main portion 2121, and the end parts 21221 respectively extend into the recesses 21211 of the main portion 2121. In other words, the branch portions 2122 may be symmetrically formed at two opposite sides of the main portion 2121 which substantially has a rectangular shape.

In this embodiment, the electronic device casing 20 is horizontally placed into the rack 10, and the second plates 22 of the electronic device casing 20 located opposite to each other are fixed to two opposite sides of the rack 10. When there are electronic components uniformly placed on the first plate 21, the downward bending deformation may mainly occur at the central portion of the first plate 21. Cross sections of the first plate 21 along a first direction D1 and a second direction D2 can reflect the deformation of the first plate 21 more obviously, where the first direction D1 is, for example, parallel to the second plate 22, and the second direction D2, for example, intersects the first direction D1. For example, the second direction D2 is non-parallel and non-perpendicular to the first direction D1. In other embodiments, the second direction D2 may be at an angle to a diagonal line of an embossing unit of the first plate 21, and the angle may be ±2 degrees. In a case that the embossing unit of the first plate 21 is in a square shape, an angle θ between the second direction D2 and the first direction D1 may fall within a range from 43 degrees to 47 degrees, such as 45 degrees. As shown in FIG. 3, in one of the embossing structures 212, the connection parts 21222 and the main portion 2121 may extend along a direction perpendicular to the first direction D1, and the end parts 21221 respectively extend towards the recesses 21211.

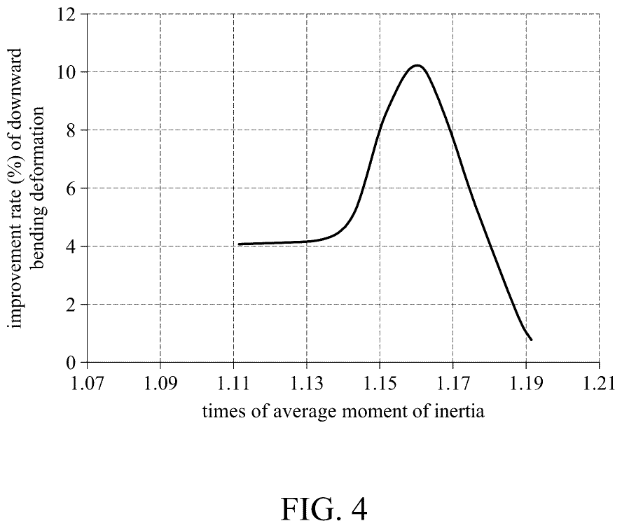

By simulating a force to be applied on a plate with embossing structures and a flat plate without any embossing structure, a relationship between times of average moment of inertia and improvement rate of downward bending deformation of the plate with the embossing structures relative to the flat plate without any embossing structure may be summarized in, for example, FIG. 4, where FIG. 4 is a curve chart showing the aforementioned relationship. Times of the average moment of inertia of the plate with the embossing structures relative to the flat plate without any embossing structure represent that the ratio of the average moment of inertia of cross sections of the plate with the embossing structures in one direction to the average moment of inertia of cross sections of the flat plate without any embossing structure in such direction. As a result, when the times of the average moment of inertia of the cross sections of the plate with the embossing structures in such direction fall within the range from 1.14 to 1.18, the improvement rate of downward bending deformation may be up to 4% to 10%. When the times of the average moment of inertia of the cross sections of the plate with the embossing structures in such direction fall within the range from 1.15 to 1.17, the improvement rate of downward bending deformation may be up to 8% to 10%.

In this embodiment, the times of the average moment of inertia of the cross sections of the first plate 21 in the first direction D1 and the second direction D2 fall within the range from 1.14 to 1.18. The times of the average moment of inertia of the cross sections of the first plate 21 in the first direction D1 represent that, in the first direction D1, the ratio of the average moment of inertia of the cross sections of the first plate 21 to the average moment of inertial of the cross sections of a flat plate having the same size as the first plate 21 but without any embossing structure. Similarly, the times of the average moment of inertia of the cross sections of the first plate 21 in the second direction D2 represent that, in the second direction D2, the ratio of the average moment of inertia of the cross sections of the first plate 21 to the average moment of inertial of the cross sections of a flat plate having the same size as the first plate 21 but without any embossing structure.

In this embodiment, the embossing structures 212 are formed on the support surface 2111 of the support portion 211 of the first plate 21, and the times of the average moments of inertia of the cross sections of the first plate 21 in the first direction D1 and the second direction D2 fall within the range from 1.14 to 1.18, which can achieve lightweight requirement and carbon reduction requirement while satisfying the structural strength of the first plate 21. Preferably, the times of the average moments of inertia of the cross sections of the first plate 21 in the first direction D1 and the second direction D2 may fall within the range from 1.15 to 1.17, which can further increase the structural strength of the first plate 21 so as to reduce the downward bending deformation amount of the first plate 21.

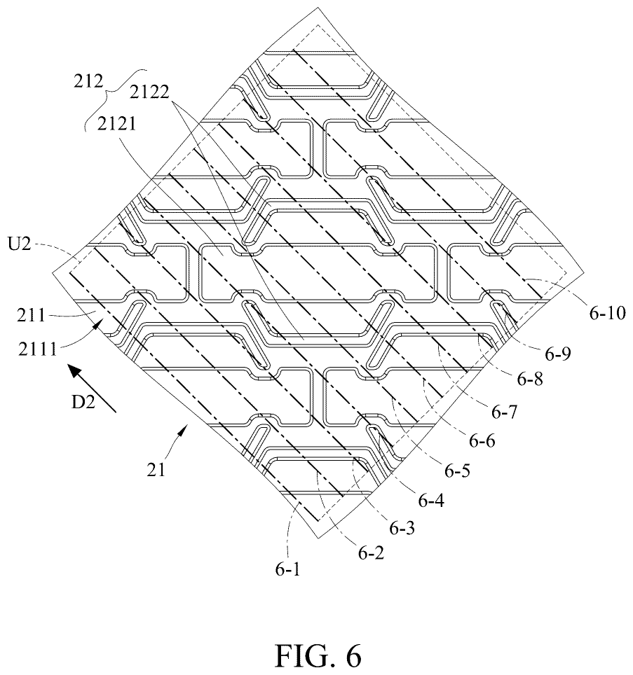

The following paragraphs will take some examples for illustration. Referring to FIGS. 3, 5 and 6, FIG. 5 is a partially enlarged view of a unit of a first plate along a first direction in FIG. 3, and FIG. 6 is a partially enlarged view of a unit of the first plate along a second direction in FIG. 3.

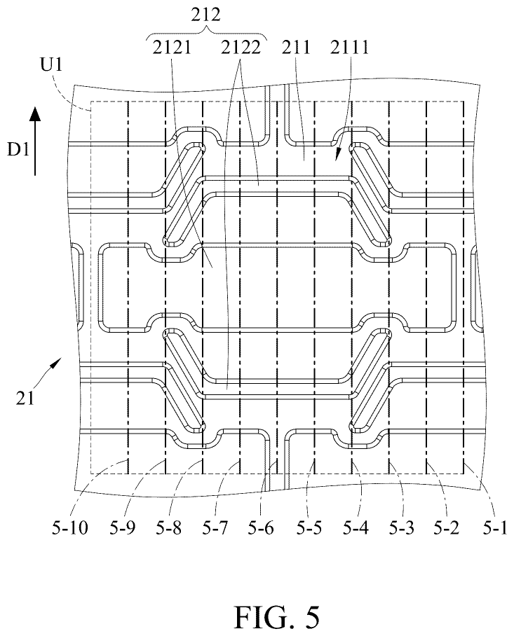

In order to clearly illustrate the average moment of inertia of the cross sections of the first plate 21 in the first direction D1 and the second direction D2, the following descriptions take a unit U1 (e.g., shown in FIG. 5) of the first plate 21 in the first direction D1 and a unit U2 (e.g., shown in FIG. 6) of the first plate 21 in the second direction D2 for instance.

In the first direction D1, one unit U1 of the first plate 21 is shown in FIG. 5. Assuming that the unit U1 shown in FIG. 5 is a square portion of 50 mm×50 mm, the thickness of the support portion 211 is 1 mm, the heights of the main portions 2121 and the branch portions 2122 of the embossing structures 212 formed on the support surface 2111 are 0.2 mm, and the unit U1 is cut into ten cross sections 5-1˜5-10 along the first direction D1 with the same intervals, the moment of inertia of each of the cross sections 5-1˜5-10 can be calculated by a computer software based on formula of moment of inertia, I=∫y² dA, and is listed in Table 1.

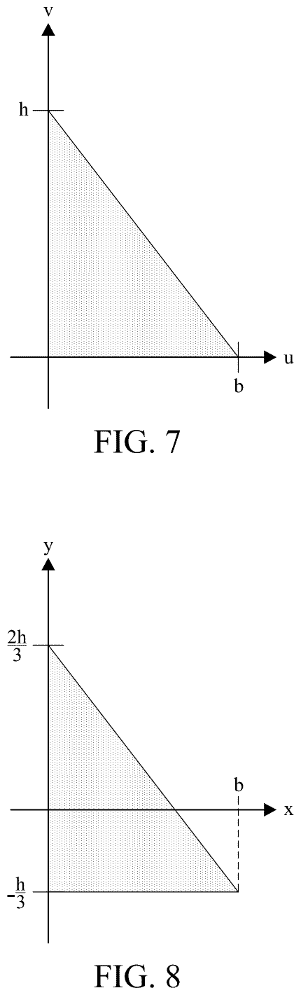

In order to explain how to calculate the moment of inertia of one cross section, the following explanations are given as the cross section is simplified to be in a triangular shape. Referring to FIGS. 7 and 8, FIG. 7 shows a cross section in u-v coordinate system, and FIG. 8 shows the cross section in x-y coordinate system. The first step is to calculate an area of the cross section shown in FIG. 7, which can be obtained from the following equations:

$${A = \int dA = \int \int dvdu = {\int }_{0}^{b} v d u = {\int }_{0}^{b} ( h - \frac{h}{b} u ) d u = h u - \frac{h}{2 b} {u}^{2} \vert}_{0}^{b} = \frac{1}{2} bh .$$

Then, the second step is to calculate the centroid of the cross section in v-axis direction, which can be obtained from the following equation,

$${v}_{c} = \frac{\int v d A}{A} , where$$

$${\int vdA = \int \int vdudv = {\int }_{0}^{b} u v d v = {\int }_{0}^{h} ( bv - \frac{b}{h} {v}^{2} ) dv = \frac{{bu}^{2}}{2} - \frac{b}{3 h} {u}^{3} \vert}_{0}^{h} = \frac{1}{6} {bh}^{2} ,$$

and thus

$${v}_{c} = \frac{\int vdA}{A} = \frac{\frac{1}{6} {bh}^{2}}{\frac{1}{2} bh} = \frac{h}{3} .$$

Then, as shown in FIG. 8, the third step is to upshift the coordinate system to make x-axis of the upshifted coordinate system pass through the centroid of the cross section. Then, the fourth step is to calculate the moment of inertia of the cross section according to the shifted coordinate system, which can be obtain from the following equations:

$${{I}_{x x} = \int {y}^{2} d A = \int x {y}^{2} d y = \int ( \frac{2}{3} b - \frac{b}{h} y ) {y}^{2} dy = \\ \int ( \frac{2}{3} {by}^{2} - \frac{b}{h} {y}^{3} ) dy = \frac{2}{9} {by}^{3} - \frac{b}{4 h} {y}^{4} \vert}_{- \frac{1}{3} h}^{\frac{2 h}{3}} = \frac{1}{36} {bh}^{3} ,$$

where “dA” is a small area in the cross section, and “y” is a distance from such small area to x-axis.

TABLE 1

| Cross sections | Moments of inertia (mm⁴) |
|---|---|
| 5-1 | 4.698769 |
| 5-2 | 4.811584 |
| 5-3 | 4.930271 |
| 5-4 | 4.930271 |
| 5-5 | 4.811584 |
| 5-6 | 4.698769 |
| 5-7 | 4.811584 |
| 5-8 | 4.930271 |
| 5-9 | 4.930271 |
| 5-10 | 4.811584 |
| Average | 4.836496 |

As for a flat plate having the same size as the unit U1 but without any embossing structure, the average moment of inertia of the cross sections of the flat plate in the first direction D1 is about 4.166667 mm⁴. As a result, in the first direction D1, the times of the average moment of inertia of the cross sections 5-1-5-10 of the unit U1 relative to the average moment of inertia of the cross sections of the flat plate having the same size as the unit U1 but without any embossing structure is about 1.161. In other words, in the case that the average moment of inertia of the cross sections of the flat plate in the first direction D1 is 4.166667 mm⁴, the range from 1.14 to 1.18 times 4.166667 mm⁴ equals the range from 4.75000038 mm⁴ to 4.91666706 mm⁴, and the range from 1.15 to 1.17 times 4.166667 mm⁴ equals 4.79166705 mm⁴ to 4.87500039 mm⁴. The average moment of inertial of the cross sections 5-1-5-10 of the unit U1 is about 4.836496 mm⁴, which not only falls within the range from 4.75000038 mm⁴ to 4.91666706 mm⁴, but also falls within the range from 4.79166705 mm⁴ to 4.87500039 mm⁴.

In the second direction D2, one unit U2 of the first plate 21 is shown in FIG. 6. Assuming that the unit U2 shown in FIG. 6 is a square portion of 70.1 mm×70.1 mm, the thickness of the support portion 211 is 1 mm, the heights of the main portions 2121 and the branch portions 2122 of the embossing structures 212 formed on the support surface 2111 are 0.2 mm, and the unit U2 is cut into ten cross sections 6-1˜6-10 along the second direction D2 with the same intervals, the moment of inertia of each of the cross sections 6-1˜6-10 can be calculated based on formula of moment of inertia, I=∫y² dA, and is listed in Table 2.

TABLE 2

| Cross sections | Moments of inertia (mm⁴) |
|---|---|
| 6-1 | 6.846542 |
| 6-2 | 6.731957 |
| 6-3 | 6.971736 |
| 6-4 | 6.971835 |
| 6-5 | 6.732086 |
| 6-6 | 6.846545 |
| 6-7 | 6.732086 |
| 6-8 | 6.971835 |
| 6-9 | 6.971736 |
| 6-10 | 6.731957 |
| Average | 6.850832 |

As for a flat plate having the same size as the unit U2 but without any embossing structure, the average moment of inertia of the cross sections of the flat plate in the second direction D2 is about 5.892557 mm⁴. As a result, in the second direction D2, the times of the average moment of inertia of the cross sections 6-1-6-10 of the unit U2 relative to the average moment of inertia of the cross sections of the flat plate having the same size as the unit U2 but without any embossing structure is about 1.163. In other words, in the case that the 10 average moment of inertia of the cross sections of the flat plate in the second direction D2 is 5.892557 mm⁴, the range from 1.14 to 1.18 times 5.892557 mm⁴ equals the range from 6.71751498 mm⁴ to 6.95321726 mm⁴, and the range from 1.15 to 1.17 times 5.892557 mm⁴ equals 6.77644055 mm⁴˜6.89429169 mm⁴. The average moment of inertial of the cross sections 6-1-6-10 of the unit U2 is about 6.850832 mm⁴, which not only falls within the range from 6.71751498 mm⁴ to 6.95321726 mm⁴, but also falls within the range from 6.77644055 mm⁴ to 6.89429169 mm⁴.

Compared the first plate 21 with the embossing structures 212 and the flat plate without any embossing structure which are suffered from a same force (e.g., 15 kgw), the times of the average moments of inertia of the cross sections of the first plate 21 with the embossing structures 212 in the first direction D1 and the second direction D2 are respectively 1.161 and 1.163, the downward bending deformation of the first plate 21 is improved about 10% compared to that of the flat plate without any embossing structure. In some specific load cases (e.g., non-uniform load cases), the downward bending deformation of the first plate 21 may be improved up to 13%. Therefore, the first plate 21 with the embossing structures 212 can have a strong structural strength. In addition, even the overall thickness of the first plate 21 (e.g., the sum of the thickness of the support portion 211 and the thicknesses of the embossing structures 212) and the thickness of the flat plate without any embossing structure are equal to each other (e.g., 1.2 mm), the first plate 21 with the embossing structures 212 can be manufactured with less material, such that the first plate 21 is lighter than the flat plate without any embossing structures, thereby meeting the lightweight requirement and carbon reduction requirement while satisfying the structural strength of the first plate 21.

In the above paragraphs, the times of the average moments of inertia of the cross sections of the first plate 21 in the first direction D1 and the second direction D2 are obtained by comparing the flat first plate 21 with the flat plate without any embossing structure. In some other embodiments, when the first plate is a curved plate, the moment of inertia of the first plate may be obtained by projecting the first plate onto a plane and then performing calculation; that is, the curved plate may be transformed to the flat plate, and the embossing structures protruding from the support surface are the part to be considered only.

Note that the average moments of inertia of the cross sections of the units U1 and U2 of the first plate 21 in the first direction D1 and the second direction D2 are not restricted to being obtained from 10 cross sections. In some other embodiments, the average moments of inertia of the cross sections of the units U1 and U2 of the first plate in the first direction and the second direction may be obtained from another number of cross sections. For example, the average moments of inertia of the cross sections of the units U1 and U2 of the first plate in the first direction and the second direction may be obtained from 6 or 20 cross sections which are spaced apart from one another by the same intervals. In some examples, the intervals between adjacent two cross sections may not be greater than 2.5 mm. In a case that the average moments of inertia of the cross sections of the units U1 and U2 of the first plate in the first direction and the second direction are obtained from 6 cross sections, the average moments of inertia of the cross sections of the units U1 and U2 in the first direction and the second direction may be respectively 1.148 and 1.156. In a case that the average moments of inertia of the cross sections of the units U1 and U2 of the first plate in the first direction and the second direction are obtained from 20 cross sections, the average moments of inertia of the cross sections of the units U1 and U2 in the first direction and the second direction may be respectively 1.164 and 1.159. Therefore, it can be understood that the average moments of inertia of the cross sections of the units U1 and U2 of the first plate in the first direction and the second direction may be different due to the number of the cross-sections used in the calculation. Accordingly, during the design of the embossing structures of the first plate, the number of the cross sections may be selected to calculate the average moments in the first direction and the second direction according to the desired accuracy of the times of the average moments of inertia.

Note that the shapes of the embossing structures 212 of the first plate 21 are not restricted to the shapes shown in FIG. 3. As long as the times of the average moments of inertia of the cross sections of the first plate in the first direction and the second direction fall within the range from 1.14 to 1.18, the shapes of the embossing structures of the first plate may be modified randomly.

In addition, the times of the average moments of inertia of the cross sections of the first plate 21 are not restricted to falling within the range from 1.14 to 1.18 merely in the first direction D1 and the second direction D2. In some other embodiments, when the first plate is also deformed obviously in a third direction (e.g., perpendicular to the first direction D1), the times of the average moments of inertia of the cross sections of the first plate in the first direction, the second direction and the third direction are required to fall within the range from 1.14 to 1.18.

Moreover, the times of the average moments of inertia of the cross sections of the first plate 21 in the first direction D1 and the second direction D2 are not restricted to both falling within the range from 1.14 to 1.18. In some other embodiments, when the design of the embossing structures of the first plate mainly consider one direction, the time of the average moment of inertia of the cross sections of the first plate in that direction is merely required to fall within the range from 1.14 to 1.18.

In the aforementioned descriptions, the electronic device casing 20 is horizontally placed into the rack 10, and two opposite sides of the electronic device casing 20 are fixed to the rack 10, but the disclosure is not limited thereto. In some other embodiments, the electronic device casing may be vertically placed into the rack. In such a case, the times of the average moments of inertia of the cross sections of the first plate in other directions are required to fall within the range from 1.14 to 1.18.

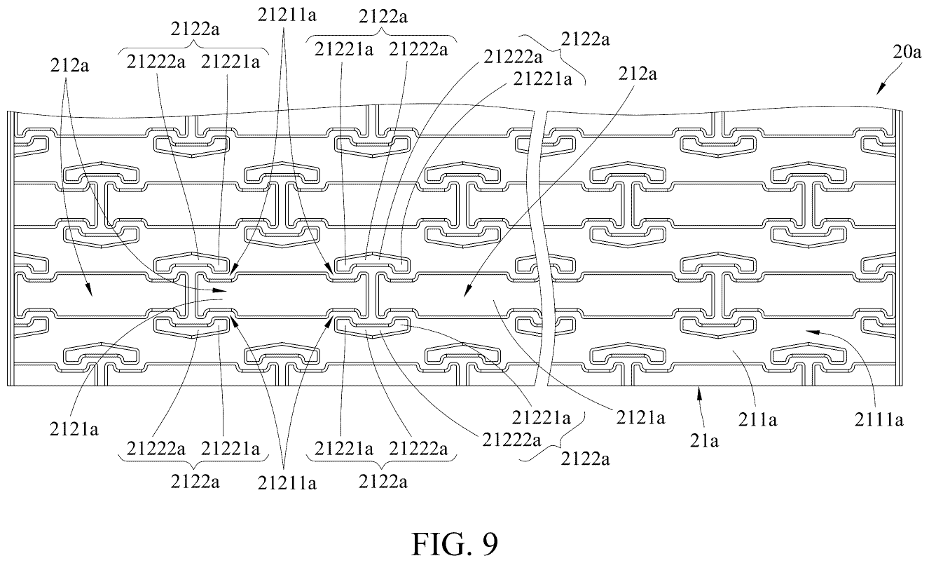

Then, referring to FIG. 9, FIG. 9 is a top view of an electronic device casing according to a second embodiment of the disclosure.

The electronic device casing 20a of this embodiment is similar to the electronic device casing 20 of the previous embodiment, and the main difference between them is the shapes of the embossing structures of the first plate. Therefore, the following paragraphs merely introduce such difference, and the same parts between them will not be repeatedly introduced.

In this embodiment, each of embossing structures 212a of a first plate 21a of the electronic device casing 20a includes a main portion 2121a and four branch portions 2122a. In each of the embossing structures 212a, the main portion 2121a, for example, has four recesses 21211a, two of the recesses 21211a are located at one side of the main portion 2121a and are spaced apart from each other, and the other two of the recesses 21211a are located at another side of the main portion 2121a and are spaced apart from each other. Each of the branch portions 2122a includes an end part 21221a and a connection part 21222a connected to each other. In each of the embossing structures 212a, the two end parts 21221a of two of the branch portions 2122a respectively correspond to two of the recesses 21211a located at one side of the main portion 2121a, and the two end parts 21221a of the other two of the branch portions 2122a respectively correspond to two of the recesses 21211a located at another side of the main portion 2121a. As shown in FIG. 9, the recesses 21211a are symmetrically recessed inwards from two opposite long sides of the main portion 2121a which substantially has a rectangular shape. In two of the embossing structures 212a located adjacent to each other, the two end parts 21221a of two of the branch portions 2122a are connected to each other via the two connection parts 21222a, and the two end parts 21221a of other two of the branch portions 2122a are connected to each other via the two connection parts 21222a.

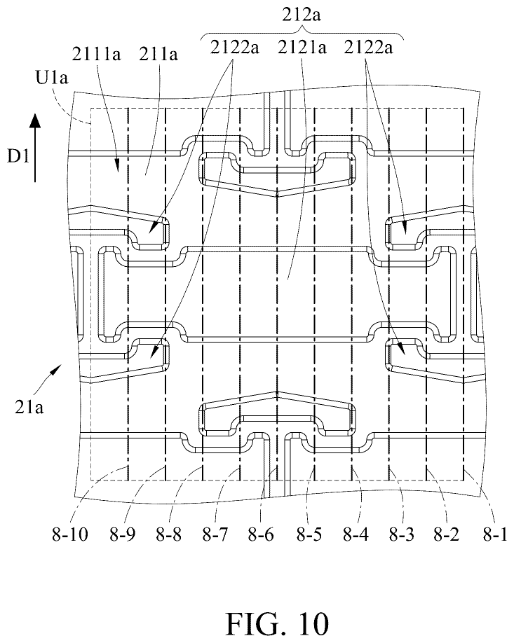

Referring to FIG. 10, FIG. 10 is a partially enlarged view of a unit of a first plate along a first direction in FIG. 9.

In the first direction D1, one unit U1a of the first plate 21a is shown in FIG. 10. Assuming that the unit U1a shown in FIG. 10 is a square portion of 50 mm×50 mm, the thickness of a support portion 211a of the first plate 21a is 1 mm, the heights of the main portions 2121a and the branch portions 2122a of the embossing structures 212a formed on a support surface 2111 of the support portion 211a are 0.2 mm, and the unit U1a is cut into ten cross sections 8-1˜8-10 along the first direction D1 with the same intervals, the moment of inertia of each of the cross sections 8-1˜8-10 can be calculated by a computer software based on formula of moment of inertia, I=∫y² dA, and is listed in Table 3.

TABLE 3

| Cross sections | Moments of inertia (mm⁴) |
|---|---|
| 8-1 | 4.727699 |
| 8-2 | 4.798599 |
| 8-3 | 5.035815 |
| 8-4 | 5.036103 |
| 8-5 | 4.798598 |
| 8-6 | 4.727445 |
| 8-7 | 4.798598 |
| 8-8 | 5.036103 |
| 8-9 | 5.035815 |
| 8-10 | 4.798599 |
| Average | 4.879338 |

As for a flat plate having the same size as the unit U1a but without any embossing structure, the average moment of inertia of the cross sections of the flat plate in the first direction D1 is about 4.166667 mm⁴. As a result, in the first direction D1, the times of the average moment of inertia of the cross sections 8-1-8-10 of the unit U1a relative to the average moment of inertia of the cross sections of the flat plate having the same size as the unit U1a but without any embossing structure is about 1.171.

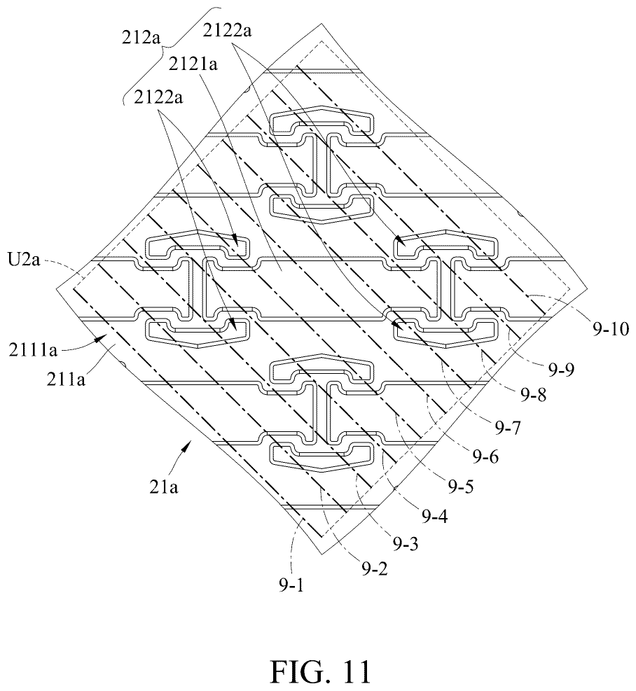

Referring to FIG. 11, FIG. 11 is a partially enlarged view of a unit of the first plate along a second direction in FIG. 9.

In the second direction D2, one unit U2a of the first plate 21a is shown in FIG. 11. Assuming that the unit U2a shown in FIG. 11 is a square portion of 70.1 mm×70.1 mm, the thickness of the support portion 211a is 1 mm, the heights of the main portions 2121a and the branch portions 2122a of the embossing structures 212a formed on the support surface 2111a are 0.2 mm, and the unit U2a is cut into ten cross sections 9-1˜9-10 along the second direction D2 with the same intervals, the moment of inertia of each of the cross sections 9-1˜9-10 can be calculated based on formula of moment of inertia, I=∫y² dA, and is listed in Table 4.

TABLE 4

| Cross sections | Moments of inertia (mm⁴) |
|---|---|
| 9-1 | 6.689948 |
| 9-2 | 6.708811 |
| 9-3 | 6.742207 |
| 9-4 | 6.742410 |
| 9-5 | 6.708788 |
| 9-6 | 6.689955 |
| 9-7 | 6.708788 |
| 9-8 | 6.742410 |
| 9-9 | 6.742207 |
| 9-10 | 6.708811 |
| Average | 6.718433 |

As for a flat plate having the same size as the unit U2a but without any embossing structure, the average moment of inertia of the cross sections of the flat plate in the second direction D2 is about 5.892557 mm⁴. As a result, in the second direction D2, the times of the average moment of inertia of the cross sections 9-1-9-10 of the unit U2a relative to the average moment of inertia of the cross sections of the flat plate having the same size as the unit U2a but without any embossing structure is about 1.140.

Compared the first plate 21a with the embossing structures 212a and the flat plate without any embossing structure which are suffered from a same force (e.g., 15 kgw), the times of the average moments of inertia of the cross sections of the first plate 21a with the embossing structures 212a in the first direction D1 and the second direction D2 are respectively 1.171 and 1.140, the downward bending deformation of the first plate 21a is improved about 8% compared to that of the flat plate without any embossing structure. Therefore, the first plate 21a with the embossing structures 212a can have a strong structural strength. In addition, even the overall thickness of the first plate 21a and the thickness of the flat plate without any embossing structure are equal to each other (e.g., 1.2 mm), the first plate 21a with the embossing structures 212a can be manufactured with less material, such that the first plate 21a is lighter than the flat plate without any embossing structures, thereby meeting the lightweight requirement and carbon reduction requirement while satisfying the structural strength of the first plate 21a.

According to the first plate, the electronic device casing and the rack assembly, the embossing structures of the first plate are disposed on the support surface of the support portion, and the times of the average moment of inertia of cross sections of the first plate in the first direction and the second direction fall within the range from 1.14 to 1.18, which can meet the lightweight requirement and carbon reduction requirement while satisfying the structural strength of the first plate.

Preferably, the times of the average moment of inertia of the cross sections of the first plate in the first direction and the second direction fall within the range from 1.15 to 1.17, which can further increase the structural strength of the first plate so as to reduce the downward bending deformation amount of the first plate.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A rack assembly, comprising:
a rack; and
an electronic device casing, mounted in the rack and comprising:
a first plate, comprising a support portion and at least one embossing structure, wherein the support portion has a support surface, the at least one embossing structure is formed on the support surface, and times of an average moment of inertia of cross sections of the first plate in a first direction fall within a range from 1.14 to 1.18; and
two second plates, standing on two opposite sides of the support surface of the support portion of the first plate, wherein the first plate and the two second plates together form an accommodation space.

2. The rack assembly according to claim 1, wherein the at least one embossing structure comprises a plurality of embossing structures, and the plurality of embossing structures are arranged in an array.

3. The rack assembly according to claim 1, wherein times of an average moment of inertia of cross sections of the first plate in a second direction fall within a range from 1.14 to 1.18, and the second direction intersects the first direction.

4. The rack assembly according to claim 3, wherein the second direction is non-perpendicular to the first direction.

5. The rack assembly according to claim 1, wherein the times of the average moment of inertia of the sections of the first plate in the first direction fall within a range from 1.15 to 1.17.

6. The rack assembly according to claim 1, wherein the two second plates are respectively mounted on two opposite sides of the rack, and the first direction is parallel to the two second plates.

7. An electronic device casing, comprising:
a first plate, comprising:
a support portion, having a support surface; and
at least one embossing structure, formed on the support surface, wherein times of an average moment of inertia of cross sections of the first plate in a first direction fall within a range from 1.14 to 1.18; and
two second plates, standing on two opposite sides of the support surface of the support portion of the first plate, wherein the first plate and the two second plates together form an accommodation space.

8. The electronic device casing according to claim 7, wherein the at least one embossing structure comprises a plurality of embossing structures, and the plurality of embossing structures are arranged in an array.

9. The electronic device casing according to claim 7, wherein times of an average moment of inertia of cross sections of the first plate in a second direction fall within a range from 1.14 to 1.18, and the second direction intersects the first direction.

10. The electronic device casing according to claim 9, wherein the second direction is non-perpendicular to the first direction.

11. The electronic device casing according to claim 7, wherein the times of the average moment of inertia of the sections of the first plate in the first direction fall within a range from 1.15 to 1.17.

12. The electronic device casing according to claim 7, wherein the at least one embossing structure has a main portion and a plurality of branch portions, the main portion has a plurality of recesses, the plurality of recesses are respectively located at two opposite sides of the main portion, and the plurality of branch portions correspond to the plurality of recesses.

13. The electronic device casing according to claim 12, wherein the plurality of recesses comprises four recesses, two of the four recesses are located at one side of the main portion and are spaced apart from each other, the other two of the four recesses are located at another side of the main portion and are spaced apart from each other, the plurality of branch portions comprises two branch portions, each of the two branch portions includes two end parts and a connection part connected to the two end parts, the two end parts of one of the two branch portions respectively correspond to two of the four recesses located at one side of the main portion, and the two end parts of the other one of the two branch portions respectively correspond to the other two of the four recesses located at another side of the main portion.

14. The electronic device casing according to claim 12, wherein the at least one embossing structure comprises a plurality of embossing structures arranged in an array; in each of the plurality of embossing structures, the plurality of recesses comprises four recesses, two of the four recesses are located at one side of the main portion and are spaced apart from each other, the other two of the four recesses are located at another side of the main portion and are spaced apart from each other, the plurality of branch portions comprises four branch portions, each of the four branch portions comprises an end part and a connection part connected to the end part, the two end parts of two of the four branch portions respectively correspond to two of the four recesses located at one side of the main portion, the two end parts of the other two of the four branch portions respectively correspond to the other two of the four recesses located at another side of the main portion; in two of the plurality of embossing structures located adjacent to each other, the two end parts of two of the branch portions are connected to each other via the two connection parts, and the two end parts of other two of the branch portions are connected to each other via the two connection parts.

15. The electronic device casing according to claim 7, wherein the first direction is parallel to the two second plates.

16. A plate, comprising:
a support portion, having a support surface; and
at least one embossing structure, formed on the support surface;
wherein times of an average moment of inertia of cross sections of the plate in a first direction fall within a range from 1.14 to 1.18.

17. The plate according to claim 16, wherein times of an average moment of inertia of cross sections of the plate in a second direction fall within a range from 1.14 to 1.18, and the second direction intersects the first direction.

18. The plate according to claim 17, wherein the second direction is non-perpendicular to the first direction.

19. The plate according to claim 16, wherein the times of the average moment of inertia of the sections of the plate in the first direction fall within a range from 1.15 to 1.17.

20. The plate according to claim 16, wherein the at least one embossing structure has a main portion and a plurality of branch portions, the main portion has a plurality of recesses, the plurality of recesses are respectively located at two opposite sides of the main portion, and the plurality of branch portions correspond to the plurality of recesses.
